(19) United States
(12) Patent Application Publication
(10) Pub. No.: US 2017/0025641 A1
(43) Pub. Date: Jan. 26, 2017

(54) Organic Light-Emitting Diode Device and Manufacturing Method Thereof and Organic Light-Emitting Display Panel

(71) Applicant: EverDisplay Optronics (Shanghai) Limited, Shanghai (CN)

(72) Inventors: Lei Zhang, Shanghai (CN); Zhao Wang, Shanghai (CN); Yanhu Li, Shanghai (CN)

(21) Appl. No.: 15/214,191

(22) Filed: Jul. 19, 2016

(30) Foreign Application Priority Data
Jul. 21, 2015 (CN) 201510431857.3

(51) Int. Cl. H01L 51/52; H01L 51/50; H01L 27/32; H01L 51/56

(52) U.S. Cl. CPC H01L 51/5265; H01L 51/56; H01L 51/5056; H01L 51/5072; H01L 51/5271; H01L 27/3248; H01L 27/3258

(57) ABSTRACT

The invention relates to the field of display device technology, more particularly, to an organic light-emitting diode device and a manufacturing method thereof and an organic light-emitting display panel, which changes the traditional micro-cavity structure, spin-coatings the liquid filling agent on the cathode layer to form the micro-cavity adjusting layer, and make it between the cover and the cathode layer, on the one hand, controls the thickness of the filling agent by spin-coating to change the resonance node of OLED, to achieve the strongest resonance effect, and at the same time avoid the defect of high cost of traditional evaporation; on the other hand, configuring the micro-cavity adjusting layer on the cathode layer, when OLED in working state, the length of the electric current passing through significantly shortens, the resistance reduces, and effectively reduces the working voltage of OLED device and improves the emitting efficiency of OLED device.

### CROSS-REFERENCE TO RELATED APPLICATIONS

The present application claims priority to and the benefit of Chinese Patent Application No. CN 201510431857.3, filed on Jul. 21, 2015, the entire content of which is incorporated herein by reference.

### BACKGROUND OF THE INVENTION

1. Field of the Invention

The invention relates to the field of display device technology, more particularly, to an organic light-emitting diode device and a manufacturing method thereof and an organic light-emitting display panel.

2. Description of the Related Art

Display devices, such as OLED (organic light-emitting diode), have been widely used in digital products, due to its features like lightweight, thin, and power saving. OLED display technology is different compared with the traditional LCD (Liquid Crystal Display) display mode, which needs no backlight and uses very thin organic material coating and glass substrate; the organic materials will shine when electric current passes through. As a display device, the OLED display screen may also be affected by environmental factors; especially in a strong light environment, the display effect of the OLED display screen will also decline.

As shown in FIG. 1, an ordinary micro-cavity structure used in OLED structure helps to improve the luminance and contrast of OLED, thus improving the performance of OLED as a whole. The ordinary micro-cavity structure (particularly the top-emitting OLED structure) mainly uses Node 1 to resonate, and mainly includes an anode layer 11, an OLED layer (comprising a hole-injecting layer (HIL) 12, a hole-transporting layer (HTL) 13, a micro-cavity adjusting layer 14, an emitting layer (EML) 15, an electron-transporting layer (ETL) 16), a cathode layer 17 and a cover 18 locating over the cathode, stacked in order from bottom to top. Wherein, the anode 11, the OLED layer and the cathode 17 constitute an optical resonance cavity (the length of the cavity is about 200 nm) A; since the hole-transporting layer 13 of the OLED layer of the structure not only has a hole-transporting function, but also has the role of micro-cavity adjustment, so the total thickness of the configured OLED layer is relatively thick, wherein the micro-cavity adjusting layer accounts for about half of the total evaporation thickness (100 nm), thus results in a longer evaporation time, and extending the length the electric current passed through, increasing the resistance, and greatly reducing emitting efficiency of the OLED device.

Therefore, providing a new technical solution to solve the above-mentioned technical defects becomes the direction those skilled in the art dedicating to.

### SUMMARY OF THE INVENTION

In view of the deficiency of prior art, the technical solution of the invention provides an organic light-emitting diode device and a manufacturing method thereof and an organic light-emitting display panel. In the technical solution of the invention, a micro-cavity adjusting layer is spin-coated on a cathode during the manufacturing process of OLED display device, to make the micro-cavity adjusting layer between a cover and a cathode layer, thus reducing the manufacturing cost, and thinning the thickness of the cathode of OLED device, and easier to adjust the node, and achieving encapsulation without frames.

The technical solution the invention used to solve the above-mentioned technical problem is as follows:

An organic light-emitting diode device, comprising:
an anode layer;
an OLED device layer, covering on the anode layer;
a cathode layer, covering on the OLED device layer;
a micro-cavity adjusting layer, disposed on the cathode layer; and
a cover, covering on the micro-cavity adjusting layer.

Preferably, in the above-mentioned organic light-emitting diode device, the OLED device layer comprises:
a hole-transporting layer, an emitting layer and an electron-transporting layer stacked in order from bottom to top;
wherein, the hole-transporting layer covers on the anode layer, and the cathode layer covers on the electron-transporting layer.

Preferably, in the above-mentioned organic light-emitting diode device, the micro-cavity adjusting layer locates on the cathode layer and contacts with the cathode.

Preferably, the above-mentioned organic light-emitting diode device further comprises a semitransparent-and-semireflecting layer disposed between the micro-cavity adjusting layer and the cover.

Preferably, the above-mentioned organic light-emitting diode device further comprises an index matching layer between the semitransparent-and-semireflecting layer and the cover, wherein the index matching layer is a light transmission layer and having a refractive index greater than 1.

Preferably, in the above-mentioned organic light-emitting diode device, the semitransparent-and-semireflecting layer is made by a material selecting from a group consisting of metal, inorganic matter and organic matter.

Preferably, in the above-mentioned organic light-emitting diode device, the micro-cavity adjusting layer is made with a material of epoxy resin.

The invention also provides a manufacturing method of the organic light-emitting diode device, comprising:
providing a substrate;
forming an anode layer on the substrate;
forming an OLED device layer on the anode layer;
forming a cathode layer on the OLED device layer;
spin-coating a layer of liquid filling agent on an upper surface of the cathode layer, to form a micro-cavity adjusting layer contacted with the cathode layer; and
forming a cover on the micro-cavity adjusting layer.

Preferably, in the above-mentioned manufacturing method, the liquid filling agent is made with a material of epoxy resin.

Preferably, the above-mentioned manufacturing method, before the cover forming step, further comprises:
coating a semitransparent-and-semireflecting layer on an upper surface of the micro-cavity adjusting layer by spin-coating, to adjust an intensity of micro-cavity effect of the micro-cavity adjusting layer.

Preferably, in the above-mentioned manufacturing method, the semitransparent-and-semireflecting layer is made by a material selecting from a group consisting of metal, inorganic matter and organic matter.

The invention also provides an organic light-emitting display panel based on the above-mentioned organic light-emitting diode device, comprising:
an array substrate;
a thin-film transistor, disposed on the array substrate;
an organic light-emitting diode device, configured on the thin-film transistor; and
a drain of the thin-film transistor electrically connecting to an anode of the organic light-emitting diode device.

Preferably, in the above-mentioned organic light-emitting display panel, wherein further comprises:
a buffer layer, covering on the array substrate;
a gate insulating layer, covering on the buffer layer;
an insulating layer, covering on the gate insulating layer;
a planarizing layer, covering on the insulating layer and contacting with the anode layer of the organic light-emitting diode device; and
the thin-film transistor is distributed in the gate insulating layer, the insulating layer and the planarizing layer.

The invention discloses an organic light-emitting diode device and a manufacturing method thereof and an organic light-emitting display panel, which changes the traditional micro-cavity structure, and spin-coats the liquid filling agent on the cathode to form the micro-cavity adjusting layer and make it between the cover and the cathode layer. On one hand, the thickness of the filling agent is controlled by spin-coating to change the resonance node of OLED, to achieve the strongest resonance effect, and at the same time avoid the defect of high cost of traditional evaporation; on the other hand, the micro-cavity adjusting layer is configured on the cathode layer; when OLED is working, a length passed through by the electric current is significantly shortened, the resistance is reduced, and the working voltage of OLED device is effectively reduced, and the emitting efficiency of OLED device is improved, and at the same time the liquid filling agent has encapsulation effect after being roasted and solidified, which is convenient to achieve encapsulation without frames.

### BRIEF DESCRIPTIONS OF THE DRAWINGS

The accompanying drawings, together with the specification, illustrate exemplary embodiments of the present disclosure, and, together with the description, serve to explain the principles of the present invention.

FIG. 1 is a structural diagram of an organic light-emitting diode device of a traditional OLED;

FIG. 2 is a structural diagram of an organic light-emitting diode device of an OLED of the invention;

FIG. 3 is a procedure diagram of manufacturing an organic light-emitting diode device of the invention;

FIG. 4 is a structural diagram of an organic light-emitting display panel of the invention.

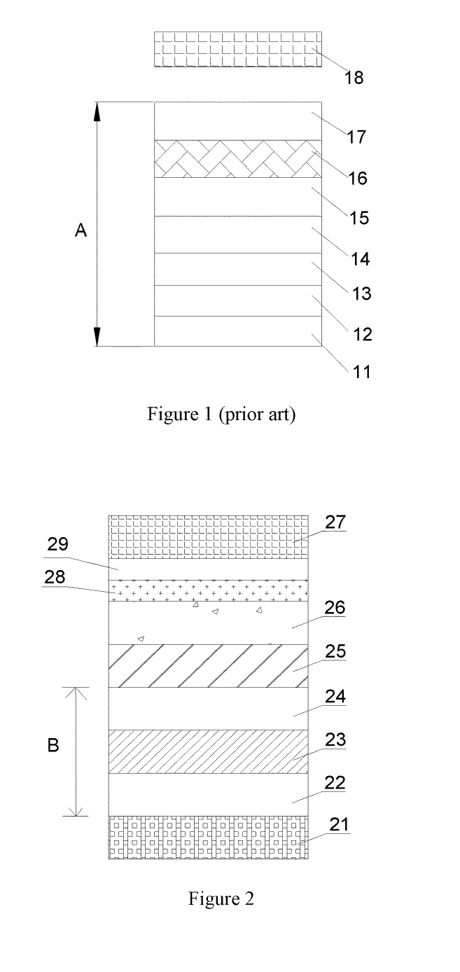

### DETAILED DESCRIPTION

The present invention will now be described more fully hereinafter with reference to the accompanying drawings, in which exemplary embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” or “has” and/or “having” when used herein, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

As used herein, “around”, “about” or “approximately” shall generally mean within 20 percent, preferably within 10 percent, and more preferably within 5 percent of a given value or range. Numerical quantities given herein are approximate, meaning that the term “around”, “about” or “approximately” can be inferred if not expressly stated.

As used herein, the term “plurality” means a number greater than one.

Hereinafter, certain exemplary embodiments according to the present disclosure will be described with reference to the accompanying drawings.

### Embodiment 1

To solve the defects like the longer evaporation time, the extending length of the electric current passed through, the increasing resistance, and the reducing emitting efficiency of the OLED device caused by a thicker total thickness of evaporation of the micro-cavity adjusting layer in prior art, the invention provides a micro-cavity adjusting structure, specifically as shown in FIG. 2, the general scheme of which is to configure the micro-cavity adjusting layer, which traditionally needs to be evaporated, on the cover by spin-coating, to achieve the purpose of the technical solution of the invention.

As shown in FIG. 2, in the embodiment of the invention, the organic light-emitting diode device mainly comprises:

An anode layer 21; the anode layer is an ITO/Ag/ITO anode layer specifically in the embodiment of the invention; in this field, the anode layer 21 can also choose other metal with high reflectivity and high work function.

An OLED device layer (marked as ‘B’ in the Figure); the OLED device layer covers on the upper surface of the anode layer 21. In the embodiment of the invention, preferably, the OLED device layer mainly comprises a hole-transporting layer 22, an emitting layer 23 and an electron-transporting layer 24, stacked in order from bottom to top, wherein the hole-transporting layer 22 of the OLED device layer covers on the upper surface of the anode layer 21. In addition, the OLED device layer can also selectively comprise a hole-injecting layer and an electron-injecting layer etc (not shown in the Figures of the embodiment).

A cathode layer 25; in the embodiment of the invention, preferably, the cathode layer 25 takes metal with high transmittance, such as the lanthanide series metal, Mg, Ag and alloy etc.; when the cathode layer in the state of being a thin film, all the metals have two properties, transmission and reflection. Of course, the difference of the metal materials, the difference of the alloys and the different proportions of alloys will affect the transmittance and reflectance of the cathode layer. In this embodiment, metal with higher transmittance is selected, which is to make the emitting effect of the OLED device achieved by transparent cathode layer the best. Wherein, the cathode layer 25 covers on the upper surface of the electron-transporting layer 24 of the OLED device layer.

A micro-cavity adjusting layer 26 and a cover 27; in the embodiment of the invention, the micro-cavity adjusting layer 26 locates on the upper surface of the cathode layer 25, and the cover 27 locates on the micro-cavity adjusting layer 26; thus the micro-cavity adjusting layer 26 and the cover 27 integrated and configured on the cathode layer 25, or the micro-cavity adjusting layer 26 is disposed between the cover 27 and the cathode layer 25. In a detailed description, the technical solution of the invention configures the micro-cavity adjusting layer, which traditionally needs to be evaporated, on the cover by spin-coating, which has obvious structural differences.

In the embodiment of the invention, forming a liquid filling agent on the cover by spin-coating; preferably, the liquid filling agent is mainly made with a material of macromolecular resin, like epoxy resin etc. The liquid filling agent has encapsulation effect after being roasted and solidified, and can achieve encapsulation without frames.

A semitransparent-and-semireflecting layer 28 is configured between the micro-cavity adjusting layer 26 and the cover 27 also, the semitransparent-and-semireflecting layer 28 can be made by a material selecting from a group consisting of metal, inorganic matter and organic matter etc., as long as the semitransparent-and-semireflecting layer has appropriate transmittance and reflectance, such as evaporating a layer of metal film (Ag, the preferable thickness is 10˜15 nm) or spin-coating organic matter. It should be notice that the effect of the semitransparent-and-semireflecting layer 28 is to adjust the intensity of micro-cavity effect; the reflectance of the semitransparent-and-semireflecting layer 28 determines the half-wave width of luminescent spectrum, and affects the purity of the light emitted, therefore the half-wave width is adjusted to be smaller in order to improve the purity.

As a preferable embodiment, selectively, an index matching layer (IML) 29 can also be disposed between the semitransparent-and-semireflecting layer 28 and the cover 27, the effect of which is to improve the external light extraction, and enhance the luminous efficiency, which can be improve about 20%. In addition, it should be notice that not only does the traditional cathode structure have the conductive function, but also its reflectance determines the intensity of micro-cavity effect (mainly used to adjust the light color purity). Yet, in this embodiment, the cathode 25 has been defined as a high transmittance cathode, which only has conductive function. The semitransparent-and-semireflecting layer 28 is responsible for the function of adjusting the intensity of micro-cavity effect, which is traditionally the responsibility of the traditional cathode. Therefore, in this embodiment, the IML layer 29 should be placed on the semitransparent-and-semireflecting layer 28. Its configuring method is still spin-coating, selecting an appropriate transparent material with refractive index greater than 1, and spin-coating it on the surface of the cover, then forming the semitransparent-and-semireflecting layer 28 on the surface of the index matching layer 29.

In the embodiment of the invention, when the OLED device is working (i.e. when the anode layer 21 and cathode layer 25 applying voltage), electrons in the OLED device layer enter into the emitting layer 23 through the electron-transporting layer 24 due to the effect of the voltage; similarly, holes enter into the emitting layer 23 through the hole-transporting layer 22 due to the effect of the voltage, so that the holes composite-luminescence in the emitting layer 23 together with the electrons. In the embodiment of the invention, the emitting efficiency, the contrast ratio of the OLED device and other parameters factors are all relevant to the resonant cavity; appropriate strong resonance is helpful to increase the work efficiency of the OLED device. For example: the resonance of Node 2 is stronger than the resonance of Node 1. The traditional micro-cavity structure (particularly top-emitting OLED structure) mainly takes the resonance of Node 1, and resonant cavity is mainly formed by the anode layer, the hole-injecting layer, the hole-transporting layer, the micro-cavity adjusting layer, the emitting layer, the electron-transporting layer and the cathode layer. The entire cavity length of the resonance of Node 1 is 200 nm, but the micro-cavity adjusting layer accounts for half of the entire evaporation, which leads to low efficiency of OLED and increases the manufacturing cost greatly.

The invention takes liquid filling agent and makes it on the cover as the micro-cavity adjusting layer 26 by spin-coating, and forms the resonant cavity B comprising the liquid filler agent, the cathode layer 25, the electron-transporting layer 24, the emitting layer 23, the hole-transporting layer 22 and the anode layer 21 in order. Hence, when the OLED is working, the length passed through by the electric current significantly decreases (the resistance decreases), which effectively reduces the working voltage of the OLED device. In addition, the difficulty of spin-coating is lower than evaporation, and the cost also greatly reduces; at the same time, the invention can adjust the resonance nodes by controlling the thickness of the liquid filling agent, such as: when the thickness of the liquid filling agent formed on the substrate is 100 nm, the OLED device uses the resonance of Node 1; when the thickness of the liquid filling agent formed on the substrate is 250 nm, the OLED device uses the resonance of Node 2, which is the strongest resonance, to improve the work efficiency of OLED device.

### Embodiment 2

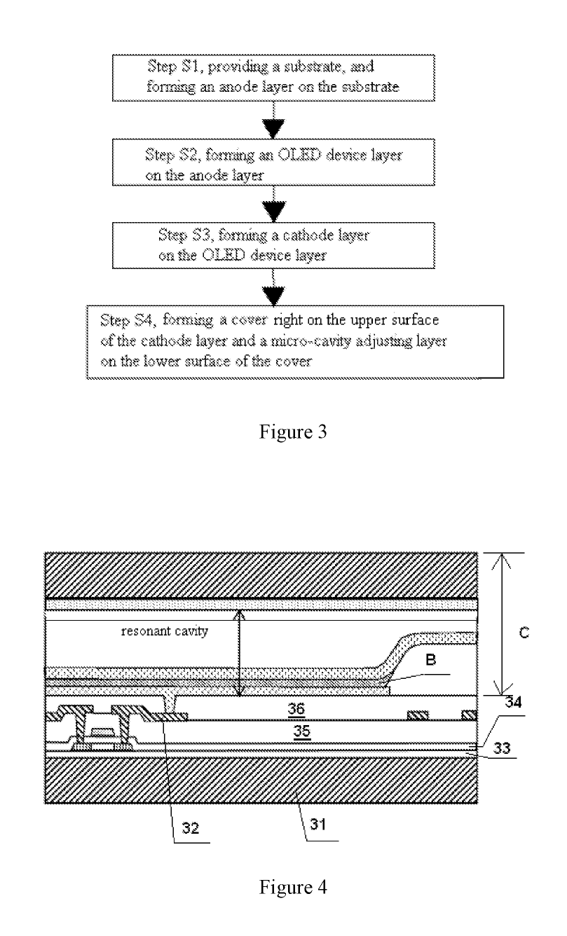

Based on the above-mentioned organic light-emitting diode device, the invention also provides the manufacturing method of the organic light-emitting diode device, specifically as the procedure diagram shown in FIG. 3.

Step S1, providing a substrate, and forming an anode layer on the substrate. In the embodiment of the invention, the anode layer specifically is an ITO anode layer; in this field, the anode layer can also be other metal with high reflectivity.

Step S2, forming an OLED device layer on the anode layer; as an emitting device, the OLED device layer mainly comprises a hole-transporting layer, an emitting layer and an electron-transporting layer, stacked in order from bottom to top; wherein the hole-transporting layer of the OLED device layer covers on the anode layer.

Step S3, forming a cathode layer on the upper surface of the OLED device layer; in the embodiment, the metal with higher transmittance is chose to be the cathode layer (i.e. the transparent cathode layer), so as to make the emitting effect of the OLED device best.

Step S4, forming a cover right on the upper surface of the cathode layer, and a micro-cavity adjusting layer on the lower surface of the cover.

In the embodiment of the invention, the step S4 specifically comprises: coating a semitransparent-and-semireflecting layer on the lower surface of the cover by spin-coating; continuing spin-coating liquid filling agent on the semitransparent-and-semireflecting layer as a micro-cavity adjusting layer. It should be notice that the thickness of the liquid filling agent is the micro-cavity adjusting layer, and the micro-cavity adjusting layer directly contacts with the cathode.

In the embodiment of the invention, preferably, the semitransparent-and-semireflecting layer is made by a material selecting from a group consisting of metal, inorganic matter and organic matter, and the liquid filling agent is made with a material of epoxy resin.

Of course, an index matching layer (IML) may also be disposed between the semitransparent-and-semireflecting layer and the cover; the index matching layer is a light transmission layer and having a refractive index greater than 1, the manufacturing method of which has been elaborated in Embodiment 1 and will not be repeated here.

### Embodiment 3

Based on the above-mentioned organic light-emitting diode device, the invention also provides an organic light-emitting display panel using the organic light-emitting diode device, and its structure shown in FIG. 4 comprises:

an array substrate 31; a buffer layer 33, covering on the array substrate 31; a gate insulating layer 34, covering on the buffer layer 33; an insulating layer 35, covering on the gate insulating layer 34; a planarizing layer 36, covering on the insulating layer 35.

In the gate insulating layer 34, the insulating layer 35 and the planarizing layer 36, there also provides a thin-film transistor 32 located above the array substrate 31.

The organic light-emitting diode device (marked C in the Figure) described in Embodiment 1 is configured on the planarizing layer 36; wherein as described in Embodiment 1, the organic light-emitting diode device C mainly comprises (FIG. 4 has not specifically marked for the layout, please refer to FIG. 2): the anode 21 and the drain of the thin-film transistor 32 is electrically connected to the anode 21 of the organic light-emitting diode device C; the organic emitting layer B (comprising the hole-transporting layer 22, the emitting layer 23 and the electron-transporting layer 24 described in Embodiment 1), the cathode 25, the micro-cavity adjusting layer 26, the semitransparent-and-semireflecting layer 28, the index matching layer 29 (which is selectable) and the encapsulating cover 27.

Wherein, the anode 21, the organic emitting layer B, the cathode 25, the micro-cavity adjusting layer 26 and the semitransparent-and-semireflecting layer 28 of the organic light-emitting diode device C form the resonant cavity of the organic light-emitting display panel together.

In conclusion, the invention discloses an organic light-emitting diode device and a manufacturing method thereof and an organic light-emitting display panel, which changes the traditional micro-cavity structure, and spin-coats the liquid filling agent on the cover right on the cathode, so as to form the micro-cavity adjusting layer, and position it between the cover and the cathode layer. On one hand, the thickness of the filling agent is controlled by spin-coating so as to change the resonance node of OLED, to achieve the strongest resonance effect, and at the same time, the defect of high cost of traditional evaporation is avoided; on the other hand, the micro-cavity adjusting layer is configured on the cover, and when the OLED is working, the length passed through by the electric current is significantly shortened, the resistance is reduced, and the working voltage of OLED device is reduced effectively, and the emitting efficiency of OLED device is improved, and at the same time the liquid filling agent has encapsulation effect after being roasted and solidified, which is convenient to achieve encapsulation without frames.

The foregoing is only the preferred embodiments of the invention, not thus limiting embodiments and scope of the invention, those skilled in the art should be able to realize that the schemes obtained from the content of specification and figures of the invention are within the scope of the invention.

What is claimed is:

1. An organic light-emitting diode device, comprising:
an anode layer;
an OLED device layer, covering on the anode layer;
a cathode layer, covering on the OLED device layer;
a micro-cavity adjusting layer, disposed on the cathode layer; and
a cover, covering on the micro-cavity adjusting layer.

2. The organic light-emitting diode device of claim 1, wherein the OLED device layer comprises:
a hole-transporting layer, an emitting layer and an electron-transporting layer stacked in order from bottom to top; wherein,
the hole-transporting layer covers on the anode layer, and the cathode layer covers on the electron-transporting layer.

3. The organic light-emitting diode device of claim 1, wherein the micro-cavity adjusting layer locates on the cathode layer and contacts with the cathode.

4. The organic light-emitting diode device of claim 1, further comprising a semitransparent-and-semireflecting layer disposed between the micro-cavity adjusting layer and the cover.

5. The organic light-emitting diode device of claim 4, further comprising an index matching layer between the semitransparent-and-semireflecting layer and the cover, wherein the index matching layer is a light transmission layer and having a refractive index greater than 1.

6. The organic light-emitting diode device of claim 4, wherein the semitransparent-and-semireflecting layer is made with a material selecting from a group consisting of metal, inorganic matter and organic matter.

7. The organic light-emitting diode device of claim 1, wherein the micro-cavity adjusting layer is made with a material of epoxy resin.

8. A manufacturing method of the organic light-emitting diode device, comprising:
providing a substrate;
forming an anode layer on the substrate;
forming an OLED device layer on the anode layer;
forming a cathode layer on the OLED device layer;
spin-coating a layer of liquid filling agent on an upper surface of the cathode layer, to form a micro-cavity adjusting layer contacted with the cathode layer; and
forming a cover on the micro-cavity adjusting layer.

9. The manufacturing method of claim 8, wherein the liquid filling agent is made with a material of epoxy resin.

10. The manufacturing method of claim 8, before the cover forming step further comprising:
coating a semitransparent-and-semireflecting layer on an upper surface of the micro-cavity adjusting layer by spin-coating, to adjust an intensity of micro-cavity effect of the micro-cavity adjusting layer.

11. The manufacturing method as claimed in claim 10, wherein the semitransparent-and-semireflecting layer is made by a material selecting from a group consisting of metal, inorganic matter and organic matter.

12. An organic light-emitting display panel, based on the organic light-emitting diode device as claimed in claim 1, comprising:
an array substrate;
a thin-film transistor, disposed on the array substrate;
an organic light-emitting diode device, disposed on the thin-film transistor; and
a drain of the thin-film transistor electrically connecting to an anode of the organic
light-emitting diode device.

13. The organic light-emitting display panel as claimed in claim 12, further comprises:
a buffer layer, covering on the array substrate;
a gate insulating layer, covering on the buffer layer;
an insulating layer, covering on the gate insulating layer;
a planarizing layer, covering on the insulating layer and contacting with the anode layer of the organic light-emitting diode device; and
the thin-film transistor is distributed in the gate insulating layer, the insulating layer and the planarizing layer.
